(19) United States
(12) Patent Application Publication
(10) Pub. No.: US 2017/0271267 A1
(43) Pub. Date: Sep. 21, 2017

(54) SEMICONDUCTOR PACKAGING STRUCTURE

(71) Applicant: Team Expert Management Consulting Service, LTD., Taoyuan City (TW)

(72) Inventor: Lee-Sheng Yen, Taoyuan City (TW)

(21) Appl. No.: 15/357,252

(22) Filed: Nov. 21, 2016

(30) Foreign Application Priority Data
Mar. 21, 2016 (TW) 105203912

(51) Int. Cl. H01L 23/538; H01L 23/00; H01L 23/48; H01L 23/31

(52) U.S. Cl. CPC H01L 23/5389; H01L 23/5386; H01L 23/3107; H01L 24/20; H01L 24/06; H01L 23/481; H01L 2224/215; H01L 2924/01047; H01L 2924/0105; H01L 2924/01079; H01L 2924/01322; H01L 2924/014

(57) ABSTRACT

A semiconductor packaging structure includes a solder resist layer with a circuit layer embedded therein, a semiconductor element disposed on the solder resist layer and electrically connected with the circuit layer, and a dielectric encapsulating the semiconductor element. As a result, the thickness of the overall structure can be greatly reduced.

### BACKGROUND

1. Technical Field

The present disclosure relates to semiconductor packaging structures, and, more particularly, to a thin semiconductor packaging structure.

2. Description of Related Art

With the evolution of semiconductor packaging technology, the semiconductor devices have developed different packaging styles. Among them, ball grid array (referred to as BGA), such as PBGA, EBGA, FCBGA and the like, is an advanced semiconductor packaging technology. It is characterized by the use of a package substrate to accommodate a semiconductor element with solder balls implanted at the back of the package substrate in a grid pattern, so that more input/output (I/O) connections can be accommodated in the same unit area of a carrier. This meets the demand for highly integrated semiconductor chips. Additionally, the whole package unit is soldered and electrically connected to an external electronic device via these solder balls.

Furthermore, in order to be in line with the latest trends for compact, versatile high-speed and high-frequency semiconductor packages, thinner lines and smaller apertures on the circuit boards used for packaging semiconductor chips have become the main development focus. The line resolution, such as the line width, line spacing, aspect ratio and etc, of existing circuit board manufacturing process is being reduced from the traditional 100 microns to 20 microns, and even smaller line width are under development.

As shown in FIG. 1, a conventional semiconductor package 1 includes a substrate structure 10, a semiconductor chip 11 provided on top of the substrate structure 10, an encapsulant 12 encapsulating the semiconductor chip 11, and a plurality of solder balls 13 provided on the underside of the substrate structure 10.

More specifically, the substrate structure 10 is composed of a plurality of dielectric layers 100, and a circuit layer 101 is provided on each of the dielectric layers 100. The dielectric layers 100 are electrically connected with one another through a plurality of conductive blind vias 102. The solder balls 13 are electrically connected with the circuit layers 101. The substrate structure 10 may also be a package substrate with two circuit layers, a package substrate with a core board or the like.

Moreover, the semiconductor chip 11 has an active area 11a and a non-active area 11b opposite to each other. There are a plurality of electrode pads 110 on the active area 11a. The electrode pads 110 are electrically connected to the circuit layers 101 through the conductive blind vias 102.

However, in the traditional semiconductor package 1, the substrate structure 10 for carrying the semiconductor chip 11 is a package substrate with multiple layers of circuits or a package substrate with a core board. This makes the semiconductor package 1 to be generally quite thick, which does not satisfy the demands for thinner and more compact semiconductors packages.

Therefore, there is a need for a solution that addresses the aforementioned issues in the prior art.

### SUMMARY

In view of the aforementioned shortcomings of the prior art, the present disclosure provides a semiconductor packaging structure, which may include: a solder resist layer; a circuit layer embedded in the solder resist layer and having a portion exposed from the solder resist layer; a semiconductor element disposed on the solder resist layer and having the active area and the non-active area, opposite to the active area, wherein the semiconductor element is electrically connected via the active area with the portion of the circuit layer exposed from the solder resist layer; and a dielectric formed on the solder resist layer and encapsulating the semiconductor element.

In an embodiment, the solder resist layer is formed with a plurality of openings in order to expose the portion of the circuit layer.

In an embodiment, the active area of the semiconductor element includes a plurality of electrode pads electrically connected with the circuit layer.

In an embodiment, the electrode pads are electrically connected with the circuit layer via conductive elements.

In an embodiment, at least one of the conductive elements may be a silver paste, a UV curable adhesive, an anisotropic conductive film, a solder alloy, a lead-free solder or a Sn—Au eutectic solder.

In an embodiment, the non-active area of the semiconductor element is exposed from the dielectric.

In an embodiment, a metal layer is formed on the non-active area of the semiconductor element.

In an embodiment, the dielectric is made of a prepreg glass fiber fabric.

In an embodiment, at least one conductive column is formed in the dielectric, penetrates the dielectric, and is electrically connected with the circuit layer.

In an embodiment, a wiring layer is formed on the dielectric.

It can be understood from the above that the thickness of the semiconductor packaging structure in accordance with the present disclosure can be effectively reduced by employing the design of a solder resist layer with a single circuit layer instead of a substrate with multiple circuit layers or a substrate with a core board.

### BRIEF DESCRIPTION OF THE DRAWINGS

The present disclosure can be more fully understood by reading the following detailed description of the preferred embodiments, with reference made to the accompanying drawings, wherein:

FIG. 1 is a cross-sectional schematic diagram illustrating a conventional semiconductor package;

FIG. 2 is a cross-sectional schematic diagram illustrating a semiconductor packaging structure in accordance with the present disclosure; and

FIGS. 3A to 3C are cross-sectional schematic diagrams illustrating other different embodiments of the semiconductor packaging structure in accordance with the present disclosure.

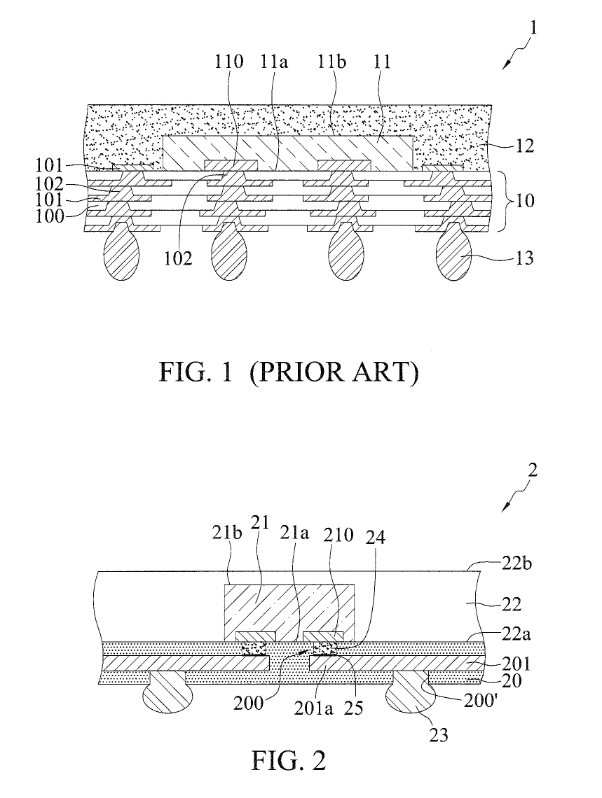

### DETAILED DESCRIPTION OF THE EMBODIMENTS

The present disclosure is described by the following specific embodiments. Those with ordinary skills in the arts can readily understand other advantages and functions of the present disclosure after reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “up”, “down”, “bottom”, “first”, “second”, “a” and the like, are for illustrative purposes only, and are not meant to limit the range implementable by the present disclosure. Any changes or adjustments made to their relative relationships, without modifying the substantial technical contents, are also to be construed as within the range implementable by the present disclosure.

FIG. 2 is a cross-sectional schematic diagram illustrating a semiconductor packaging structure 2 in accordance with the present disclosure. The semiconductor packaging structure 2 includes: a solder resist layer 20 with a circuit layer 201 embedded therein, a semiconductor element 21, and a dielectric 22.

A plurality of openings 200 are formed on the top side of the solder resist layer 20, such that a portion of the circuit layer 201 is exposed from the openings 200.

In an embodiment, the circuit layer 201 is manufactured by electroplating copper, and has a plurality of conductive pads 201a that are exposed from the openings 200.

Further, a plurality of openings 200′ may also be formed on the underside of the solder resist layer 20, such that a portion of the circuit layer 201 is exposed from the openings 200′, to allow the exposed portion to be combined with conductive elements 23 such as solder balls.

The semiconductor element 21 is provided on top of the solder resist layer 20 and electrically connected with the circuit layer 201. The semiconductor element 21 has the active area 21a and the non-active area 21b opposite to the active area 21a. There are a plurality of electrode pads 210 disposed on the active area 21a.

In an embodiment, the semiconductor element 21 may be an active element, a passive element or a combination thereof. In another embodiment, the active element may be, for example, a semiconductor chip, and the passive element may be, for example, a resistor, a capacitor or an inductor.

Moreover, conductive elements 24 may be disposed in the openings 200, such that the electrode pads 210 of the semiconductor element 21 are combined and electrically connected with the conductive pads 201a through the conductive elements 24. In an embodiment, at least one of the conductive elements 24 may be, for example, a silver paste, a UV curable adhesive (commonly known as UV glue), an anisotropic conductive film (referred to as ACF), a solder alloy, a lead-free solder or a Sn—Au eutectic solder.

In addition, the area treated layer 25 may be formed on the conductive pads 201a to facilitate the formation of the conductive elements 24.

The dielectric 22 is provided on top of the solder resist layer 20, and encapsulates the semiconductor element 21.

In an embodiment, the dielectric 22 has a first area 22a and a second area 22b opposite to the first area 22a. The dielectric 22 is laminated with the solder resist layer 20 through the first area 22a.

In an embodiment, the dielectric 22 is a prepreg glass fiber fabric composed of multiple layers of dielectric sheets. At least one of the dielectric sheets has an opening for receiving the semiconductor element 21, such that the semiconductor element 21 is embedded in the dielectric 22.

In the process of manufacturing the semiconductor packaging structure 2, for example, the circuit layer 201 is first formed in the solder resist layer 20; then, the semiconductor element 21 is disposed on top of the solder resist layer 20; and, thereafter, the dielectric 22 is laminated with the solder resist layer 20, such that the dielectric 22 encapsulates the semiconductor element 21.

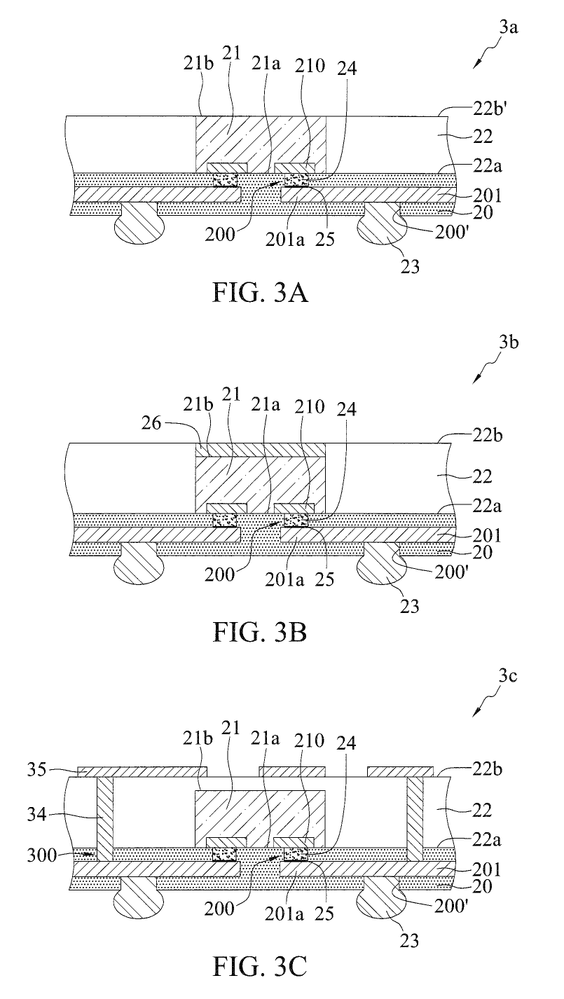

FIGS. 3A to 3C are cross-sectional schematic diagrams illustrating other different embodiments of semiconductor packaging structures 3a, 3b and 3c in accordance with the present disclosure.

As shown in FIG. 3A, in the semiconductor packaging structure 3a, a portion of the second area 22b of the dielectric 22 may be removed, such that the non-active area 21b of the semiconductor element 21 is exposed from the second area 22b′ of the dielectric 22, thereby facilitating heat dissipation of the semiconductor element 21.

In an embodiment, the non-active area 21b of the semiconductor element 21 is flush with the second area 22b of the dielectric 22.

As shown in FIG. 3B, the semiconductor packaging structure 3b further includes a metal layer 26 formed on the non-active area 21b of the semiconductor element 21, and is exposed from the second area 22b of the dielectric 22 (for example, the exposed area of the metal layer 26 is flush with the second area 22b of the dielectric 22), allowing the metal layer 26 to act as a heat dissipating layer, a stress layer or a shield layer.

As shown in FIG. 3C, in the semiconductor packaging structure 3c, the dielectric 22 replaces the traditional encapsulant. A plurality of conductive columns 34 may be formed in the dielectric 22 that communicate between first and the second areas 22a and 22b, so as to electrically connect with the circuit layer 201.

In an embodiment, a wiring layer 35 is formed on the second area 22b of the dielectric 22, and electrically connected with the circuit layer 201 through the conductive columns 34.

A plurality of another openings 300 are formed on the top side of the solder resist layer 20, such that a portion of the circuit layer 201 is exposed from the openings 300, allowing the exposed portion to be combined and electrically connected with the conductive columns 34.

Furthermore, the wiring layer 35 may be used as a heat dissipating layer, a circuit layer, a stress layer or a shield layer, depending on the needs.

In addition, by replacing a traditional encapsulant with the dielectric 22, design can be selectively made on the second area 20b of the dielectric 22. For example, depending on the needs, a circuit build-up structure (not shown) can be provided, or an electronic device (not shown), such as a package or chip, can be stacked thereon.

In summary, the thickness of the semiconductor packaging structure 2, 3a, 3b or 3c in accordance with the present disclosure can be effectively reduced by employing the design of a solder resist layer 20 with a single circuit layer 201 instead of a substrate with multiple circuit layers or a substrate with a core board.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. A semiconductor packaging structure, comprising:
a solder resist layer;
a circuit layer embedded in the solder resist layer and having a portion exposed from the solder resist layer;
a semiconductor element disposed on the solder resist layer and having an active area and an non-active area opposite to the active area, wherein the semiconductor element is electrically connected via the active area with the portion of the circuit layer being exposed from the solder resist layer; and
a dielectric formed on the solder resist layer and encapsulating the semiconductor element.

2. The semiconductor packaging structure of claim 1, wherein the solder resist layer is formed with a plurality of openings.

3. The semiconductor packaging structure of claim 2, wherein the portion of the circuit layer is exposed from the openings.

4. The semiconductor packaging structure of claim 1, further comprising a plurality of electrode pads disposed on the active area of the semiconductor element.

5. The semiconductor packaging structure of claim 4, wherein the electrode pads are electrically connected with the circuit layer.

6. The semiconductor packaging structure of claim 5, wherein the electrode pads are electrically connected with the circuit layer via conductive elements.

7. The semiconductor packaging structure of claim 6, wherein at least one of the conductive elements is a silver paste, a UV curable adhesive, an anisotropic conductive film, a solder alloy, a lead-free solder or a Sn—Au eutectic solder.

8. The semiconductor packaging structure of claim 1, wherein the non-active area of the semiconductor element is exposed from the dielectric.

9. The semiconductor packaging structure of claim 1, further comprising a metal layer formed on the non-active area of the semiconductor element.

10. The semiconductor packaging structure of claim 1, wherein the dielectric is made of a prepreg glass fiber fabric.

11. The semiconductor packaging structure of claim 1, further comprising at least one conductive column disposed in the dielectric.

12. The semiconductor packaging structure of claim 11, wherein the at least one conductive column penetrates the dielectric and is electrically connected with the circuit layer.

13. The semiconductor packaging structure of claim 1, further comprising a wiring layer formed on the dielectric.
